(19) United States
(12) Patent Application Publication
(10) Pub. No.: US 2012/0001631 A1
(43) Pub. Date: Jan. 5, 2012

(54) ULTRA-LOW FIELD NUCLEAR MAGNETIC RESONANCE METHOD TO DISCRIMINATE AND IDENTIFY MATERIALS

(75) Inventors: Michelle A. Espy, Los Alamos, NM (US); Andrei Nikolaevich Matlashov, Los Alamos, NM (US); Petr Lvovich Volegov, Los Alamos, NM (US); Algis V. Urbaitis, Albuquerque, NM (US); Robert Henry Kraus, JR., Los Alamos, NM (US)

(73) Assignee: Los Alamos National Security, LLC, Los Alamos, NM (US)

(21) Appl. No.: 13/044,433

(22) Filed: Mar. 9, 2011

Related U.S. Application Data
(60) Provisional application No. 61/312,004, filed on Mar. 9, 2010.

(51) Int. Cl. G01R 33/44

(52) U.S. Cl. 324/309

(57) ABSTRACT

An ultra-low field (ULF) nuclear magnetic resonance (NMR) and/or magnetic resonance imaging (MRI) system can be used for rapid identification and discrimination of materials, e.g., liquid in opaque containers and/or materials in or on human bodies. The system utilizes the ability of ULF NMR/MRI to measure NMR parameters in magnetic fields that can be easily changed in field strength and orientation.

### STATEMENT OF FEDERAL RIGHTS

The United States government has rights in this invention pursuant to Contract No. DE-AC52-06NA25396 between the United States Department of Energy and Los Alamos National Security, LLC for the operation of Los Alamos National Laboratory.

### FIELD OF THE INVENTION

The present invention relates to an improved apparatus and methods for rapid identification of materials. For example, these methods may be used to screen small containers for security measures or for quality control. However, the device utilized could be scaled for other applications including medical diagnostics. The methods of the present invention relate to an ultra-low field (ULF) nuclear magnetic resonance (NMR) and/or magnetic resonance imaging (MRI) system, useful for rapid identification and discrimination of materials, e.g., liquid in opaque containers and/or materials in or on human bodies.

### BACKGROUND OF THE INVENTION

Recent emphasis on security has placed higher demands on development of detection of threats, including liquid explosives. At the same time, many industrial and medical applications would benefit from rapid ways to ascertain if materials conform to a specified composition or quality. Any means for detection for public use must be non-invasive, rapid, and be able to distinguish potential threats from, e.g., beverages or common personal care products. However many of the present techniques used fall short. Most present techniques for determining the chemical composition inside a closed container rely on X-ray, Raman spectroscopy, or trace detection. However X-ray does not directly measure chemical properties, instead it measures density and atomic number. Raman spectroscopy requires clear bottles and liquids. Trace detection requires presence of at least some material outside the container or opening of the container. Presently there is no non-contact high throughput method for determination of chemical composition of a material inside a closed container. This has resulted in cumbersome security regulations at airports, and an impediment to the transportation of liquids.

Nuclear magnetic resonance (NMR) techniques have long been used to investigate properties of materials ranging from chemical samples to the human body. When spatial encoding of the information is used, it is referred to as magnetic resonance imaging, or MRI. NMR instruments typically employ large superconducting magnets that produce high magnetic fields.

Ultra-low field (ULF) magnetic resonance imaging in combination with SQUID (superconducting quantum interference device) detectors has been shown to be capable of non-invasively identifying certain hazardous materials in luggage and shipping containers (see U.S. Pat. No. 7,688,069 B2, Mar. 30, 2010, incorporated herein by reference). More recently this has been extended to the use of non-cryogenic induction coils (see U.S. patent application Ser. No. 12/720432, Mar. 9, 2011, incorporated herein by reference). Some advantages of ULF-MRI systems include the lack of requirement of large, powerful magnets, and the ability to analyze materials enclosed in conductive and lead shells. ULF NMR/MRI allows one to measure the NMR signal in a magnetic field (the measurement field) which is low enough that signals from the sample can penetrate through conductive containers (such as a soda can or foil lined packaging) or the presence of conducting materials does not inhibit detection of the NMR signal. The hardware also enables applications of magnetic resonance to situations where high fields are not desired due to the interaction of these fields with nearby metal, and applications where relatively inexpensive and portable NMR/MRI is desired. However, a need exists for systems that are able to conduct rapid analyses, and thus with higher throughput, and with greater sensitivity.

### SUMMARY OF THE INVENTION

The present invention meets the aforementioned need by improving on previous applications of ULF-NMR/MRI technology. The present invention utilizes the ability of ULF NMR/MRI to measure NMR parameters in magnetic fields that can be easily changed in field strength and orientation.

Some features of the present invention include: 1) a reference sample used to monitor the operational conditions of the system, 2) extraction of NMR parameters by measurement of chemical shift from a known reference sample and the sample which is being tested, 3) non-resonant spin inversion pulses to produce a “spin echo” without the use of resonant magnetic fields at the Larmor frequency (this is not possible with other NMR methods), 4) the detection axis of the sensors oriented in different directions to detect the NMR signal at different phases, 5) noise cancellation methods based on reference channels and current monitoring, and 6) use of a set of T1/T2 values and/or the frequency dependence of these values. These approaches enable higher sensitivity leading to more reliable and rapid analysis and extraction of information about chemical composition in the presence of metal in ways presently not possible by conventional NMR/MRI or even present incarnations of ULF NMR/MRI.

### BRIEF DESCRIPTION OF THE DRAWINGS

FIG. 1 shows a block diagram of the apparatus which is utilized by the method of the present invention.

FIG. 2 shows one embodiment of an assembled version of the apparatus used to implement the method of the present invention. The embodiment shown in FIG. 2 is the apparatus as it would be used for the classification of material inside of a bottle.

FIG. 3 is a cross-sectional view of the apparatus used to implement the method of the present invention.

FIG. 4 is a pulse sequence utilized by the method of the present invention.

FIG. 5 is a detailed view of one embodiment of the pulse sequence for the period ST shown in FIG. 4, for the non-resonant condition.

FIG. 6 is one embodiment of an orthogonal sensor which may be used by the method of the present invention.

### DETAILED DESCRIPTION OF THE INVENTION

In addition to identifying liquids and discriminating between harmless and potentially harmful substances in closed containers (e.g., airport security), the present invention may have a variety of applications, including but not limited to identifying materials and discriminating between harmless and potentially harmful substances in or on a mammalian (including a human) body; detecting disease states in a mammalian body; for use in combat or emergency situations; body imaging (including brain imaging), e.g. for studying anatomical structures, conducting brain studies such as neural current imaging, cancer detection, and for use with MEG applications; quality control, e.g. for food, personal care products, and other consumer goods.

The method to discriminate or identify materials can be implemented using the NMR measuring apparatus described below or any of its variations. The NMR measuring apparatus consists of the following components:

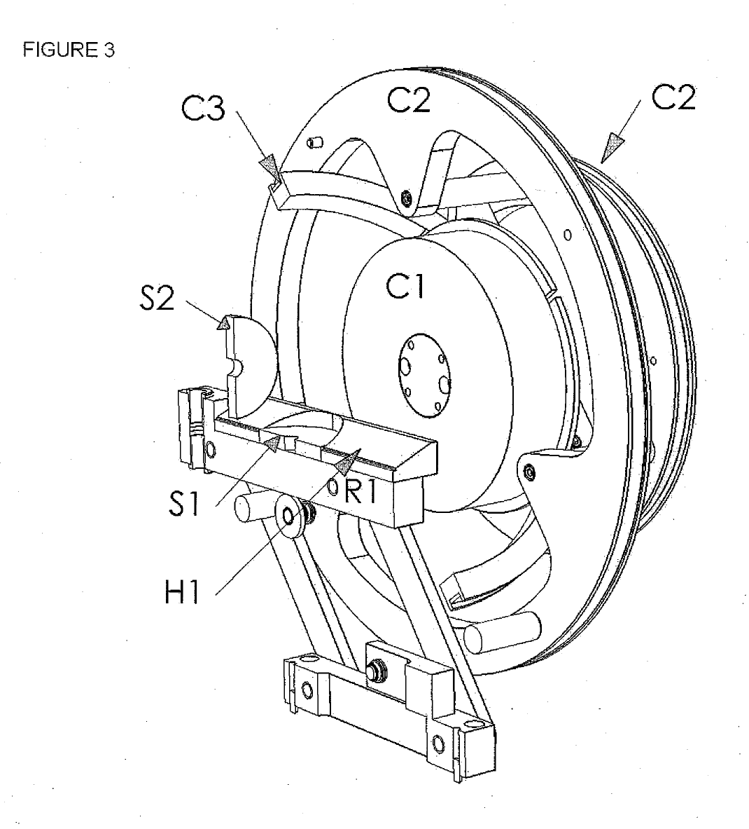

(a) One or more coils to generate a strong pre-polarizing magnetic field. Numerous configurations may be employed in order to achieve the desired field. For example there may be one flat coil placed on any surface of a sample which is being tested; two or more flat coils placed on different surfaces of the sample; or there may be a solenoid coil with a sample inside it. FIG. 3 shows one possible embodiment, in which there are one of two pre-polarizing coils placed on two opposite sides of a sample which is being tested, C1.

(b) A coil system to generate a measurement magnetic field. The coil system can be a Helmholtz coil system or any other coil system that generates a uniform field inside a sample volume. FIG. 3 shows one possible embodiment, in which there are two coils of a 4-coil system that generates a measurement magnetic field in a sample volume, C2.

(c) A spin-flip coil system that changes orientation of spins in a sample. The spin-flip coil system can be one or more coils that generates a magnetic field to produce a resonant or adiabatic pulse to reorient spins from initial orientation to any necessary final orientation. The necessary orientation will depend on the measurements being made and will be varied. FIG. 3 shows half of one circular spin-flip coil, C3.

(d) A sensor system to record the NMR signals from a sample can be assembled using one or more high sensitivity magnetometers or gradiometers. For instance, it can be a SQUID-based system or inductive coils based system, or atomic magnetometers based system or a magneto-impedance based sensor system or any other high resolution magnetic sensor. One or more sensors are optimally placed around a sample for reaching the highest possible signal-to-noise ratio (SNR). FIG. 3 shows a two-coil inductive magnetometers sensor system as an example, S1 and S2. The sensors are part of the sample holder, H1, designed for bottles.

(e) A thermometer and a heater, which can be used to measure sample temperature and make small changes to the temperature. Recording the NMR parameters at a few different temperatures may improve the accuracy of the method of the present invention and improve the ability to discriminate or identify materials.

(f, g) Computer controlled current generation and control system and a data acquisition system can be any appropriate devices and/or instruments that provide the highest possible SNR.

(h) Passive shielding can be made using a one-layer, a two-layer or a multilayer magnetically shielded enclosure using material with high magnetic permeability. For example, an active magnetic shielding system can be built using three orthogonal coils with vector reference magnetometers to provide feedback current into the coil system and compensate ambient DC and AC magnetic field in a sample volume. Passive or active magnetic shielding will eliminate external magnetic field and noise to appropriately low levels to provide the highest possible SNR and stability of the apparatus.

(i) A reference sample (volume) with an individual sensor system can be used to record the NMR signal from a known substance simultaneously with recording the NMR signal from a sample which is being tested. This additional information from a reference sample can be used for improvement of the apparatus stability and also may be used for chemical shift measurements. Use of chemical shift measurement further improves the accuracy of the method of the present invention and the ability to discriminate or identify materials. FIG. 3 shows the reference sample, R1, embedded in the sample holder, H1.

(j) Additional reference magnetometers placed inside and/or outside of the shielding system can be used with or without active shielding for suppression of ambient magnetic noise and/or transient signals associated with field switching. This also further improves the accuracy of the method of the present invention and the ability to discriminate or identify materials. An evolution field, which may be composed of the pre-polarization field, measurement field, or any combination, may also be used before NMR signal detection.

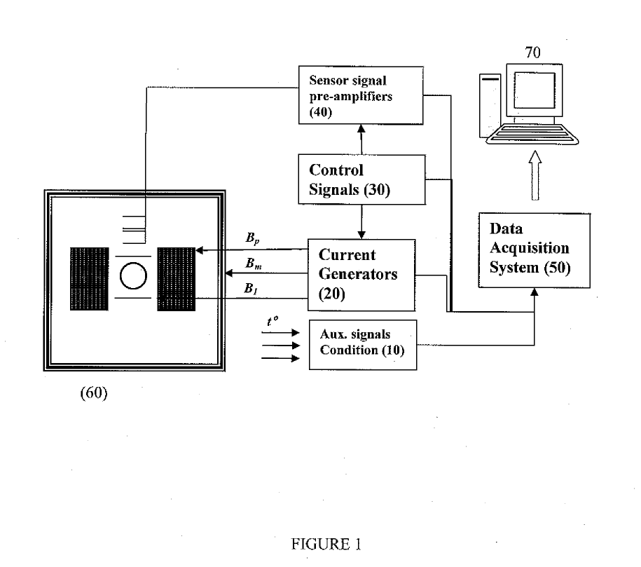

A block diagram is shown in FIG. 1. As described further below, the system has current generators module 20 which provides currents for the coil system 60. The coil system includes at least pre-polarizing field coils, measurement field coils and spin-flip pulses coils. It also can include gradient coils. The sensor signal pre-amplifiers 40 receive signals from the sensor system and provide it to a data acquisition system 50. The control signal module 30 is programmed using the computer 70 then provides all control signals in real time in accordance with a measurement protocol. The auxiliary signals condition system 10 transfers all additional information such as temperature, currents etc. into voltages and feeds them to the data acquisition system 50. The signals from the sensor system and auxiliary signals condition system 10 are processed by a computer 70 in order to extract the proper parameters and make a classification.

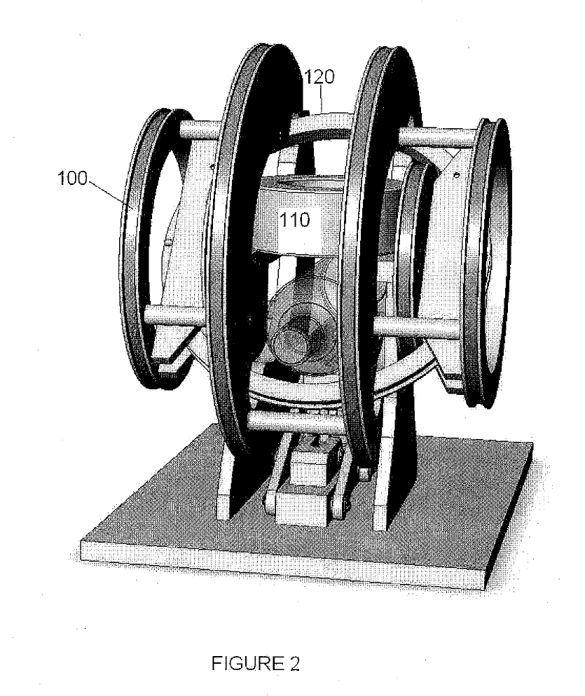

An example of such an apparatus for the measurement and classification of liquids in single bottles is shown in FIG. 2 and in cut-away in FIG. 3. Specifically, FIG. 2 shows an assembled version of one embodiment of the device as it would be used for classification of material inside a bottle. The four red coils 100 to the sides of the sample provide the measurement field. The tan coil 110 on top provides the polarization, and the green coil 120 oriented at an angle provides the spin flip.

FIG. 3 shows a cross-sectional view of one embodiment of the apparatus shown in FIG. 2. The coil configuration shown in FIG. 3 is for illustrative purposes only and is not limiting. No sample is shown, for clarity. One half of the pre-polarization coil is shown as C1. Two of the four coils for providing the measurement field are shown as C2. The spin flip coil is shown as C3. The sample holder is presented as H1, and provides a location for the two orthogonal sensor coils (S1 and S2) shown as inductive magnetometer coils, and the location for the reference sample, R1.

The sample which is being tested can be of a variety of volumes and dimensions depending on a particular application of the method of the present invention. All appropriate components of the NMR measuring apparatus can be scaled for optimal NMR signal detection depending on the application. For simplicity the use of a 500 ml cylindrical container as a sample is shown.

The present invention is a further development and improvement to the previous invention “Ultra-Low Field Nuclear Magnetic Resonance and Magnetic Resonance Imaging to Discriminate and Identify Materials (U.S. Pat. No. 7,688,069 B2, Mar. 30, 2010). The present invention utilizes new methods and developments of field-cycling (with sample pre-polarization) nuclear magnetic resonance (NMR) techniques for better discrimination and identification of materials inside an enclosed container. The method of the present invention would also be valid for magnetic resonance imaging (MRI). This technique can be realized using many different protocols for applied fields and pulses sequences, as described below.

For example, protocol may include (a) a sample pre-polarization using a strong magnetic field. This time period may be 0.1-1.0 T, however, the duration of that period of time varies depending on the particular measurement protocol; (b) fast (non-adiabatic) switching down of the pre-polarization field; (c) the much smaller measurement (read out) field is either on for the duration of steps (a) and (b) or is ramped up during the switching time (b), and is orthogonal to the pre-polarization field; (d) because the magnetization of the sample is left orthogonal to the measurement field, precession will begin; (e) the NMR signal is then recorded from the sample.

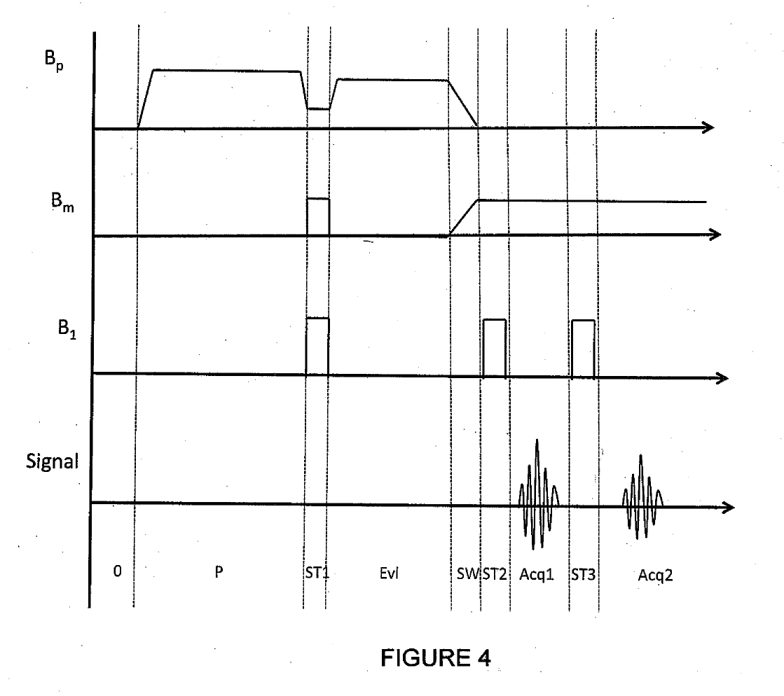

FIG. 4 shows a general embodiment of the pulse sequence. The period P is for pre-polarization of the sample to produce magnetization. This period can be varied in duration and amplitude to provide information about T1 at the polarization field. The period ST1 describes a possible spin reorientation that could occur by resonant or non-resonant methods as described below. The period Ev1 describes an optional evolution period. The period SW shows the ramp-down and application of the measurement field, although it is possible to leave the measurement field on during all previous periods. The period ST2 describes a spin reorientation that could occur by resonant or non-resonant methods as described more fully below. The period Acq1 describes the read-out of the NMR signal at the measurement field. Subsequent periods of alternating ST and Acq can be applied as needed. In all cases the field values and orientations can be variable as described below.

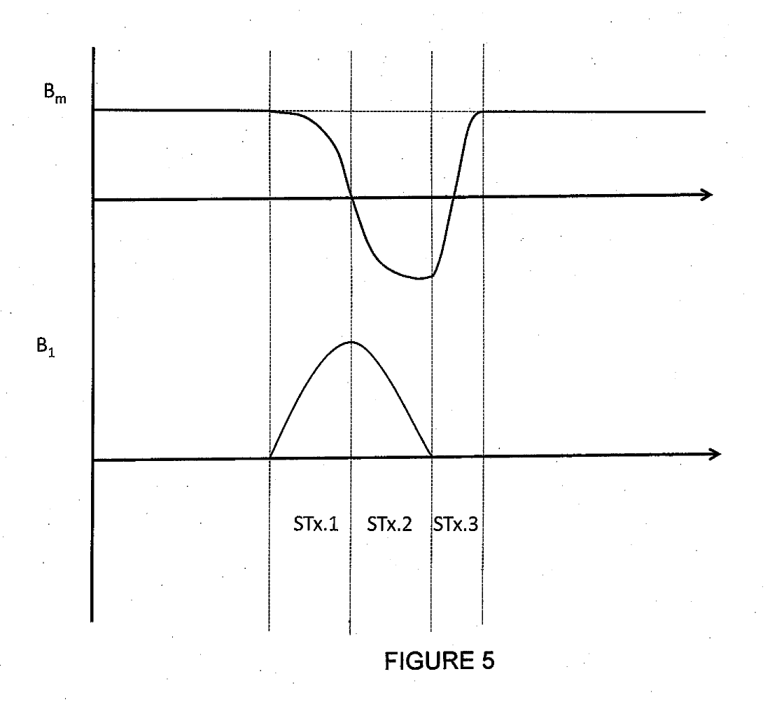

The general pulse sequence in FIG. 4 can be described as follows. (0) the initial state of the system. (P) ramp-up of the pre-polarization field to produce magnetization of the sample. The duration of (P) can vary and will provide information about T1(s) of the sample at the polarization field strength (ST1). There are two options depending on desired measurement protocol: (i) no change from (P),which is the case described above or (ii) spin reorientation in which the nuclear spins are “tipped” from the original polarization direction by either reduction of magnetic field and application of a resonant tipping pulse, or application of non-resonant rotating field pulses (described further below and in FIG. 5) to produce tipping of the magnetization, in such a way as to penetrate conducting containers (Ev1). An additional period of spin evolution may occur, if protocol dictates. In the simple example described above, this period is absent. The evolution field strength and period of evolution duration will vary (SW). In FIG. 4 ramp down of the pre-polarization field (ST2) and spin reorientation as in (ST1) part (ii) (Acq1) are shown. Read-out of the NMR signal in a magnetic field (the measurement field) which is low enough that signals from the sample can penetrate through conductive containers (such as a soda can or foil lined packaging) or the presence of conducting materials does not inhibit detection of the NMR signal. Steps (ST3) and (Acq2) can be repeated to produce additional measurements which can be used to extract T2(s) at the measurement field strength.

The above steps are repeated under differing magnetic field conditions or times. The NMR parameters are extracted from the measured data, and these include, at least one T1 at the polarization field, and at least one T2 at the measurement field from the sample material. The material is then classified based on the measured parameters to determine whether the material conforms to a specified composition or quality. In all cases the magnetic fields are generated by coils attached to a suitable power supply and signal amplifier.

The spin reorientation can be provided by two methods, resonant or non-resonant. The non-resonant case is unique to the ULF approach. In the resonant case, a time varying field B1 orthogonal to Bm is applied at the Larmor frequency, for a desired period of time to reorient the magnetization. This is typically 90 or 180 degrees but can be any value. To apply this technique in the presence of conducting containers, the field of the system is reduced such that the Larmor frequency is low enough that both the applied magnetic fields can penetrate through conductive containers (such as a soda can or foil lined packaging), or are not appreciably distorted by the presence of conducting materials.

In the non-resonant case, the original orientation of the measurement field is changed to the opposite direction adiabatically (the field changes slowly enough that the magnetization can follow). The orientation of the measurement field is then non-adiabatically restored to its original orientation, leaving the magnetization inverted. An example is shown in FIG. 5.

Classification of the material may performed in a variety of ways, as described below. The NMR parameters are compared with the NMR parameters from a known database of materials. The magnetic field dependence of T1 and T2 are obtained from measurement at different field strengths, and this field dependence is used to classify materials. The parameter T1p and the field dependence may be measured and this parameter can additionally be used to classify materials. The extracted NMR parameters may consist of a set T1 and T2 values, e.g. obtained by the method of LaPlace transform. The extracted NMR parameters may also include the diffusion coefficient of the sample derived from the measurement and used to classify materials. Specifically, the diffusion coefficient is derived from employing the PGSE (pulsed gradient spin echo) sequence or some variant thereof The extracted NMR parameters may also be combined with material properties information from other modalities (such as X-ray, raman spectroscopy, NQR, etc.) and this combined information may be used to classify the material. All of the above parameters will be used singly or in any combination to provide a more robust classification of the material.

While it is not required, it is also possible to utilize a reference sample, shown in FIG. 3 as R1, in order to compare the NMR parameters to known values. The reference sample may be part of the system and present at all times, for comparison with values from the sample which is being tested. The reference sample consists of a volume of test substance (such as DI water, fluorine containing liquid, (CH3)4Si etc.) hermetically sealed to ensure chemical stability. Around the reference sample one or two orthogonal solenoid coils are wound to detect the NMR signal. Such signals are used to monitor the operational conditions of the system, to ensure proper operation and adjust field parameters in real time.

It is also possible to utilize chemical shift information to improve identification of the sample which is being tested. Chemical shift is measured from a known reference sample and the sample which is being tested. This is accomplished by use of a reference sample as described above, and application of the following pulse sequence consisting of: 1) polarization by the pre-polarization field, and 2) spin tipping by either a) reduction of magnetic field and application of a resonant tipping pulse in such a way as to penetrate conducting-containers, or b) application of non-resonant rotating field adiabatic pulses to produce tipping of the magnetization, 3) evolution in a field high enough to produce measurable chemical shift, 4) spin inversion by either approach described in (2), and 5) measurement of the NMR signal both from reference and target material in a magnetic field low enough such that the signal can penetrate conducting containers. Chemical shift is deduced by comparing differences in phase between the reference and the sample. This sequence may be repeated several times to provide adequate discrimination of materials.

Any of the magnetic fields described above can be oriented in any direction dynamically during the pulse sequence. For example in high field MRI the main magnetic field of the scanner (which provides both measurement and polarization) is oriented in a fixed direction which cannot be changed. In the ULF-NMR technique, the measurement and evolution magnetic fields can be oriented in any direction and can change orientation during the pulse sequence.

The spin inversion pulses which are used to produce the “spin echo” during the measurement are produced by adiabatic reorientation of the measurement field by 180 degrees around an arbitrary axis orthogonal to the measurement field, followed by non-adiabatic inversion of the measurement field. The present state of the art is high field NMR/MRI where the measurement magnetic field is produced by a permanent magnet or electromagnet such that the orientation of the magnetic field cannot be arbitrarily changed. This limits NMR/MRI pulse sequences to those based on resonance pulses which require precise phase, frequency, and amplitude. In ULF NMR/MRI, the measurement fields are relatively small and cable of changing amplitude and orientation arbitrarily. This enables novel pulse sequences such as those, involving rotation of the measurement field, inversion of the measurement field. Such an approach is markedly less error prone and more robust to magnetic field inhomogeneities. The use of this technique will enable ULF NMR/MRI that is easily tunable, does not require precise (or any) resonant pulses, and does not require highly homogeneous measurement fields.

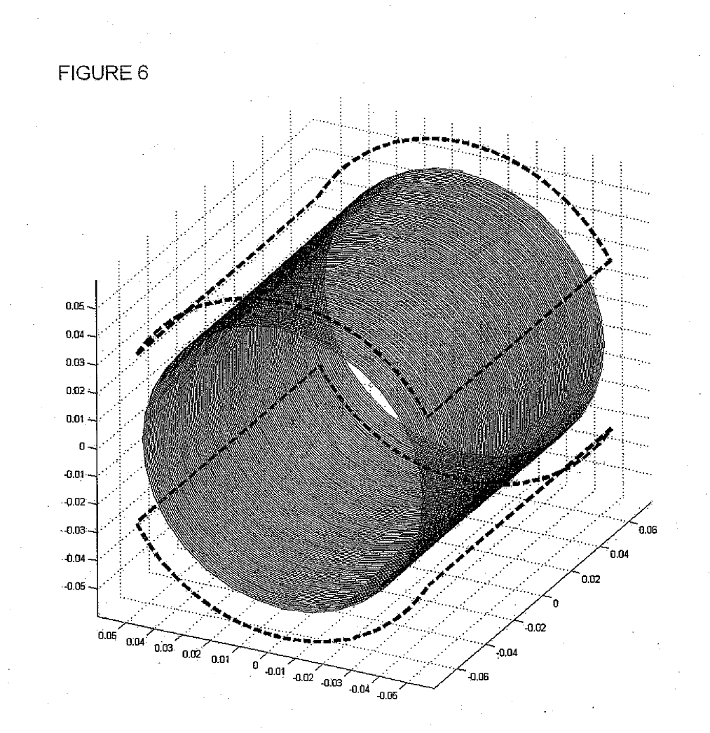

Another aspect of the present invention is the detection axis of the sensors being oriented in different directions to detect the NMR signal at different phases. For example, the sensor configuration consists of orthogonally oriented magnetometers or gradiometers (either 2 or 3 components), that are oriented such that the plane of one pick-up loop is parallel to the measurement field and the second is also parallel to the measurement field and orthogonal to the first, and the third is orthogonal to the previous two. This configuration allows for noise cancellation based on the phase content of the recorded signals. An example of orthogonally oriented sensors is shown in FIG. 6.

Some additional features which may be employed by the method of the present invention include the use of reference sensors for cancellation of background noise in real time and the measurement of current in all magnetic field producing coils to provide information on magnetic fields used for cancellation of background noise in real time

Whereas particular embodiments of the present invention have been illustrated and described, it would be obvious to those skilled in the art that various other changes and modifications can be made without departing from the spirit and scope of the invention.

What is claimed is:

1. A method for identifying a sample based on properties measured by ultra-low filed NMR comprising:
polarizing the nuclear spins within a sample by placing it in a magnetic field which is the polarization field;
letting spins evolve under a set of magnetic field and timing conditions which is the evolution field;
measuring the NMR signal in a magnetic field which is the measurement field, wherein the measurement filed is low enough that signals from the sample can penetrate through conductive containers and the presence of conducting materials does not inhibit detection of the NMR signal;
repeating the above steps under differing magnetic field or timing conditions;
extracting NMR parameters from the measured data, wherein the extracted parameters include at least one T1 at the polarization field and at least one T2 at the measurement field from the sample; and
classifying the sample based on measured parameters to determine whether the sample conforms to a specified composition or quality.

2. The method of claim 1 further comprising:
comparing the parameters with a database of materials.

3. The method of claim 1 further comprising:
measuring the temperature of the sample; and
further classifying the sample based on the temperature.

4. The method of claim 1 further comprising:
measuring T1 and T2 at different field strengths; and
obtaining the magnetic field dependence of T1 and T2 based on the measurements at different field strengths.

5. The method of claim 1 further comprising:
measuring T1p.

6. The method of claim 1 wherein the method may be used to identify a sample in a variety of environments including a factory for quality control, in a security setting to identify threat materials, in oil exploration, in a pharmaceutical plant, or for medical diagnostics.

7. The method of claim 1 wherein the extracted NMR parameters may consist of a set of T1 and T2 values.

8. The method of claim 1 further comprising:
deriving the diffusion coefficient of the sample; and
further classifying the sample based on the diffusion coefficient.

9. The method of claim 1 further comprising:
combining the extracted NMR parameters with information from other modalities including X-ray, raman spectroscopy, and NQR; and
further classifying the sample based on the combined information.

10. The method of claim 1 further comprising:
using a reference sample, wherein the reference sample consists of a small cube of test substance hermetically sealed to ensure chemical stability.

11. The method of claim 10 wherein the reference sample may consists of DI water, fluorine containing liquid, or (CH3)4Si.

12. The method of claim 10 further comprising:
detecting the NMR signal from the reference sample by winding at least one orthogonal solenoid coil around the reference sample; and
using the NMR signal from the reference sample to monitor the operational conditions of the system, to ensure proper operation and to adjust field parameters in real time.

13. The method of claim 1 further comprising:
extracting NMR parameters by measuring chemical shift from a known reference sample and the sample.

14. The method of claim 13 wherein the step of extracting NMR parameters by measuring chemical shift comprises applying a pulse sequence.

15. The method of claim 14 further comprising:
determining the chemical shift by comparing difference in phase between the sample and the reference sample.

16. The method of claim 14 wherein any of the magnetic fields can be oriented in any direction dynamically during the pulse sequence.

17. The method of claim 16 further comprising:
producing spin inversion pulses by adiabatic reorientation of the measurement field by 180 degrees around an arbitrary axis orthogonal to the measurement field, followed by non-adiabatic inversion of the measurement field.

18. The method of claim 1 further comprising:
detecting the NMR signal at different phases by utilizing sensors wherein the detection axis of the sensors are oriented in different directions.

19. The method of claim 1 wherein reference sensors are used for cancellation of background noise in real time.

20. The method of claim 1 further comprising:
measuring current in all magnetic field producing coils to provide information on magnetic fields used for cancellation of background noise in real time.
